(19) United States
(12) Patent Application Publication
(10) Pub. No.: US 2016/0197190 A1
(43) Pub. Date: Jul. 7, 2016

(54) THIN FILM TRANSISTOR PANEL AND MANUFACTURING METHOD THEREOF

(71) Applicant: Samsung Display Co., Ltd., Yongin-si (KR)

(72) Inventors: Dong Hee LEE, Hwaseong-si (KR); Sang Won SHIN, Yongin-si (KR); Hyun Ju KANG, Pocheon-si (KR); Sang Woo SOHN, Yongin-si (KR); Chang Oh JEONG, Suwon-si (KR)

(21) Appl. No.: 14/754,213

(22) Filed: Jun. 29, 2015

(30) Foreign Application Priority Data
Jan. 6, 2015 (KR) 10-2015-0001274

(51) Int. Cl. H01L 29/786; H01L 29/423; H01L 29/417; H01L 27/12; H01L 29/40

(52) U.S. Cl. CPC H01L 29/7869; H01L 27/124; H01L 27/1222; H01L 27/1259; H01L 29/401; H01L 29/41733; H01L 29/42384

(57) ABSTRACT

Provided is a thin film transistor panel including: a substrate; a gate electrode positioned on the substrate; a gate insulating layer positioned on the gate electrode; an oxide semiconductor positioned on the gate insulating layer and including an oxide layer; and a source electrode and a drain electrode positioned on the oxide semiconductor and facing each other based on a channel of the oxide semiconductor, in which the oxide layer overlaps the gate electrode and is positioned on the oxide semiconductor.

### CLAIM OF PRIORITY

This application claims the priority to and all the benefits accruing under 35 U.S.C. 119 of Korean Patent Application No. 10-2015-0001274 filed in the Korean Intellectual Property Office on Jan. 6, 2015, the entire contents of which are incorporated herein by reference.

### BACKGROUND OF THE INVENTION

1. Field of disclosure

The present invention relates to a thin film transistor panel and a manufacturing method thereof.

2. Description of the Related Art

A thin film transistor (TFT), which is used in a flat panel display such as a liquid crystal display device, an organic electroluminescence display device, or an inorganic electroluminescence display device, is used as a switching element for controlling an operation of each pixel and a driving device for driving a pixel.

The thin film transistor includes an active layer having a source region and a drain region doped with high-concentration impurities and a channel region formed between the source region and the drain region, a gate electrode positioned in a region corresponding to the channel region while being insulated from the active layer, and a source electrode and a drain electrode which are in contact with the source region and the drain region, respectively.

In recent years, the active layer of the thin film transistor is implemented by an oxide semiconductor, such that the thin film transistor may be manufactured by a low temperature process and is easy to be formed in a large size. Further, the thin film transistor using an oxide semiconductor has similar electric characteristics to those of a thin film transistor using polysilicon for the active layer.

However, a lack of oxygen ions in the oxide semiconductor leads to an increase in electron concentration and causes a negative shift of a threshold voltage (Vth) characteristic of the thin film transistor, such that a defect may occur in a panel. Further, in order to prevent oxygen ions from being stripped away during an etching process of a back channel, a sputter deposition process may be performed on an oxide semiconductor under a film-forming condition at an excessive partial pressure of oxygen, and due to the process, an amount of particles generated may be increased, and the frequency of equipment management may increase. In addition, a source/drain copper layer is oxidized due to a N20 plasma treatment process for reducing damage to a back channel at the time of forming a passivation layer, such that cracks may appear in the passivation layer, and a separate high-temperature heat treatment process may be performed to charge oxygen ions in the oxide semiconductor even after the passivation layer is deposited.

The above information disclosed in this Background section is only for enhancement of understanding of the background of the invention and therefore it may contain information that does not form the prior art that is already known in this country to a person of ordinary skill in the art.

### SUMMARY OF THE INVENTION

The present invention has been made in an effort to control an oxygen ion distribution.

The present invention has been made in an effort to improve reliability and mobility of a thin film transistor panel.

The present invention has been made in an effort to improve a degree of freedom of a continuous process and improve convenience in management of a manufacturing process of a thin film transistor panel.

Exemplary embodiments of the present invention may be used to achieve other objects that are not described in detail, in addition to the foregoing objects.

An exemplary embodiment of the present invention provides a thin film transistor panel including: a substrate; a gate electrode positioned on the substrate; a gate insulating layer positioned on the gate electrode; an oxide semiconductor positioned on the gate insulating layer and including an oxide layer; and a source electrode and a drain electrode positioned on the oxide semiconductor and facing each other based on a channel of the oxide semiconductor, in which the oxide layer overlaps the gate electrode and is positioned on the oxide semiconductor.

Herein, a top surface of the oxide layer and a top surface of the oxide semiconductor may be positioned on substantially the same plane.

Further, the oxide layer may be partially exposed.

Further, a first end of the oxide layer may overlap the source electrode, and a second end of the oxide layer may overlap the drain electrode.

Further, the oxide layer may be substantially the same as the oxide semiconductor.

Further, the oxide semiconductor may include a metal alloy semiconductor having an oxide semiconductor composition.

Further, the thin film transistor panel may further include: a barrier layer positioned on the oxide semiconductor; and a passivation layer positioned on the source electrode and the drain electrode.

Further, the thin film transistor panel may include: a data pad metal positioned on the oxide layer; and a data pad electrode positioned on the passivation layer, in which the data pad metal is connected to the data pad electrode through a connection hole.

Further, the thin film transistor panel may include: a gate pad metal positioned on the substrate; and a gate pad electrode positioned on the oxide layer, in which the gate pad metal is connected to the gate pad electrode through a connection hole.

Further, a vertical cross section of the first end of the oxide layer may be positioned on substantially the same plane as a vertical cross section of the source electrode, and a vertical cross section of the second end of the oxide layer may be positioned on substantially the same plane as a vertical cross section of the drain electrode.

Further, the thin film transistor panel may further include a passivation layer positioned on the source electrode and the drain electrode.

Further, the thin film transistor panel may include: a data pad metal positioned on the active layer between the oxide layers; and a data pad electrode positioned on the passivation layer, in which the data pad metal is connected to the data pad electrode through a connection hole.

Another exemplary embodiment of the present invention provides a method of manufacturing a thin film transistor panel, the method including: forming a gate electrode on a substrate; forming a gate insulating layer on the gate electrode; forming an oxide semiconductor on the gate insulating layer; forming an oxide layer by partially or wholly oxidizing the oxide semiconductor by anodization; and forming a source electrode and a drain electrode, which face each other based on a channel of the oxide semiconductor, on the oxide layer.

Herein, the method may further include: forming a barrier layer on the oxide layer; and forming a passivation layer on the source electrode and the drain electrode.

Further, the forming of the oxide semiconductor on the gate insulating layer may include forming the oxide semiconductor under an environment in which oxygen ions are not present.

Yet another exemplary embodiment of the present invention provides a method of manufacturing a thin film transistor panel, the method including: forming a gate electrode on a substrate; forming a gate insulating layer on the gate electrode; forming an oxide semiconductor on the gate insulating layer; forming a source electrode and a drain electrode, which face each other based on a channel of the oxide semiconductor, on the oxide semiconductor; forming a passivation layer on the source electrode and the drain electrode; and forming an oxide layer by oxidizing a channel of the oxide semiconductor by anodization.

Herein, the forming of the oxide semiconductor on the gate insulating layer may include forming the oxide semiconductor under an environment in which oxygen ions are not present.

Further, the forming of the oxide semiconductor on the gate insulating layer may include forming the oxide semiconductor under an environment in which oxygen ions are present.

Further, the method may further include forming a barrier layer on the oxide semiconductor.

According to an exemplary embodiment of the present invention, it is possible to control an oxygen ion distribution, improve reliability and mobility of a thin film transistor panel, improve a degree of freedom of a continuous process, and improve convenience in management of a manufacturing process of a thin film transistor panel.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings, in which like reference symbols indicate the same or similar components, wherein:

FIG. 1 is a cross-sectional view illustrating a thin film transistor panel according to an exemplary embodiment of the present invention.

FIGS. 2 to 6 are cross-sectional views sequentially illustrating a method of manufacturing the thin film transistor panel of FIG. 1.

FIG. 7 is a cross-sectional view illustrating a gate pad portion of FIG. 1.

FIG. 8 is a cross-sectional view illustrating a data pad portion of FIG. 1.

FIG. 9 is a cross-sectional view illustrating a thin film transistor panel according to an exemplary embodiment of the present invention.

FIG. 10 is a cross-sectional view illustrating a gate pad portion of FIG. 9.

FIG. 11 is a cross-sectional view illustrating a data pad portion of FIG. 9.

FIG. 12 is a cross-sectional view illustrating a thin film transistor panel according to an exemplary embodiment of the present invention.

FIG. 13 is a cross-sectional view illustrating a data pad portion of FIG. 10.

FIG. 14 is a cross-sectional view illustrating a thin film transistor panel according to an exemplary embodiment of the present invention.

### DETAILED DESCRIPTION OF THE INVENTION

In the following detailed description, only certain exemplary embodiments of the present invention have been shown and described, simply by way of illustration. As those skilled in the art would realize, the described embodiments may be modified in various different ways, all without departing from the spirit or scope of the present invention. Accordingly, the drawings and description are to be regarded as illustrative in nature and not restrictive. Like reference numerals designate like elements throughout the specification. In addition, detailed descriptions of the widely known technologies will be omitted.

In the specification, it will be understood that when an element such as a layer, film, region, or substrate is referred to as being “on” another element, it can be directly on the other element or intervening elements may also be present. Further, the word “on” means positioning on or below the object portion, but does not essentially mean positioning on the upper side of the object portion based on a gravity direction.

In the specification, unless explicitly described to the contrary, the word “comprise” and variations such as “comprises” or “comprising”, will be understood to imply the inclusion of stated elements but not the exclusion of any other elements. The size and thickness of each configuration shown in the drawings are arbitrarily shown for understanding and ease of description, but the present invention is not limited thereto.

A thin film transistor (TFT), which is used in a flat panel display such as a liquid crystal display device, an organic electroluminescence display device, or an inorganic electroluminescence display device, is used as a switching element for controlling an operation of each pixel and a driving device for driving a pixel.

The thin film transistor includes an active layer having a source region and a drain region doped with high-concentration impurities and a channel region formed between the source region and the drain region, a gate electrode positioned in a region corresponding to the channel region while being insulated from the active layer, and a source electrode and a drain electrode which are in contact with the source region and the drain region, respectively.

The active layer of the thin film transistor is implemented by an oxide semiconductor, such that the thin film transistor may be manufactured by a low temperature process and is easy to be formed in a large size. Further, the thin film transistor using an oxide semiconductor has similar electric characteristics to those of a thin film transistor using polysilicon for the active layer.

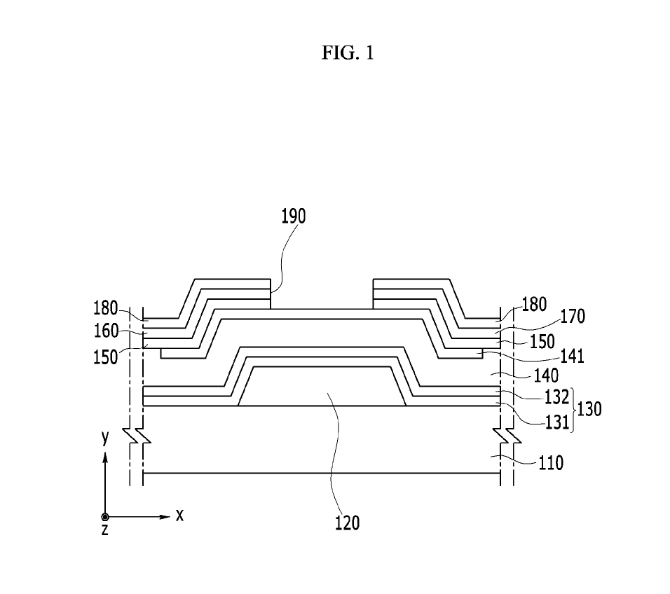

FIG. 1 is a cross-sectional view illustrating a thin film transistor panel according to an exemplary embodiment of the present invention.

A thin film transistor panel 100 of FIG. 1 includes a substrate 110, a gate electrode 120, a gate insulating layer 130, an active layer 140, an oxide layer 141, barrier layers 150, a source electrode 160, a drain electrode 170, passivation layers 180, and an opening 190.

The substrate 110 includes an insulating material such as glass or plastic.

The gate electrode 120 is positioned on the substrate 110 and includes at least one metal of an aluminum (Al)-based metal, a silver (Ag)-based metal, a copper (Cu)-based metal, a molybdenum (Mo)-based metal, chromium (Cr), tantalum (Ta), and titanium (Ti).

The gate electrode 120 may be formed of at least two layers including materials having different physical properties, respectively. For example, the gate electrode 120 may have a multi-layered structure such as Mo/Al/Mo, Mo/Al, Mo/Cu, Cu/Mo/Cu, and Ti/Cu.

The gate insulating layer 130 is positioned on the substrate 110 and the gate electrode 120, and includes at least one of insulating materials such as silicon oxide (SiOx), silicon nitride (SiNx), and silicon oxynitride (SiON).

The gate insulating layer 130 includes a first insulating layer 131 positioned on the substrate 110 and the gate electrode 120 and a second insulating layer 132 positioned on the first insulating layer 131, and the first insulating layer 131 and the second insulating layer 132 may include insulating materials having different physical properties, respectively.

The active layer 140 is positioned on the gate insulating layer 130 and includes an oxide semiconductor. In this case, the oxide semiconductor is a metal oxide semiconductor and may include oxides of metals such as zinc (Zn), indium (In), gallium (Ga), tin (Sn), and titanium (Ti) or a combination of metals such as zinc (Zn), indium (In), gallium (Ga), tin (Sn), and titanium (Ti) and oxides thereof.

The oxide layer 141 is positioned on the active layer 140, and may be formed by partially oxidizing the active layer 140.

The barrier layers 150 are positioned on the active layer 140 and the oxide layer 141 at both sides of the gate electrode 120, respectively. In this case, one end of the barrier layer 150 may overlap the gate electrode 120.

The barrier layer 150 may improve interface characteristics of the oxide layer 141 and reduce the infiltration of impurities.

The barrier layer 150 may include at least one of indium zinc oxide (ZIO) and gallium zinc oxide (GZO).

The source electrode 160 and the drain electrode 170 face each other and are positioned on the barrier layers 150 at both sides of the gate electrode 120, respectively. For example, one end of the source electrode 160 overlaps the gate electrode 120, and one end of the drain electrode 170 facing the one end of the source electrode 160 overlaps the gate electrode 120.

The passivation layers 180 are positioned on the source electrode 160 and the drain electrode 170 at both sides of the gate electrode 120, respectively. In this case, one end of the passivation layer 180 may overlap the gate electrode 120.

The passivation layer 180 may have substantially the same planar shape as the barrier layer 150, and include an insulating material.

The opening 190 is positioned on the oxide layer 141 between the source electrode 160 and the drain electrode 170.

In the thin film transistor panel 100 of FIG. 1, the oxide layer 141 may overlap the gate electrode 120. Further, a first end of the oxide layer 141 may overlap the source electrode 160, and a second end thereof may overlap the drain electrode 170. In addition, a top surface of the oxide layer 141 and a top surface of the active layer 140 may be positioned on substantially the same plane. Furthermore, the oxide layer 141 may be formed to be partially exposed. For example, the top surface of the oxide layer 141 may be formed to be partially exposed to the opening 190.

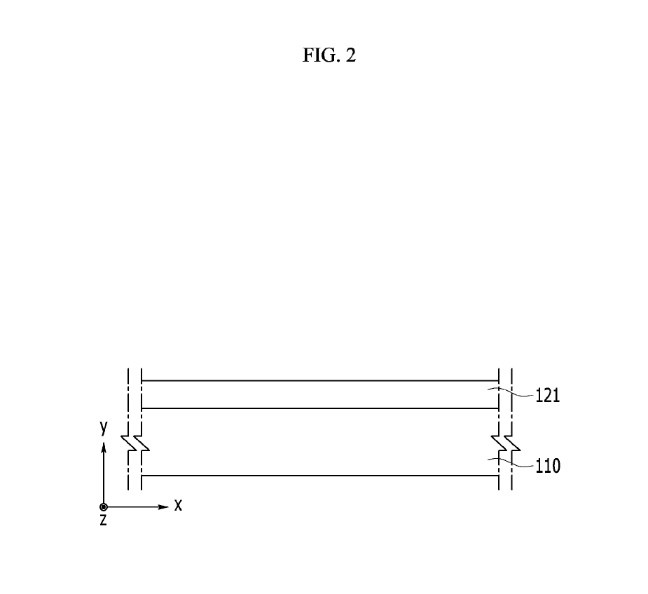

FIGS. 2 to 6 are cross-sectional views sequentially illustrating a method of manufacturing the thin film transistor panel of FIG. 1.

First, as illustrated in FIG. 2, a gate metal layer 121 is formed on a substrate 110.

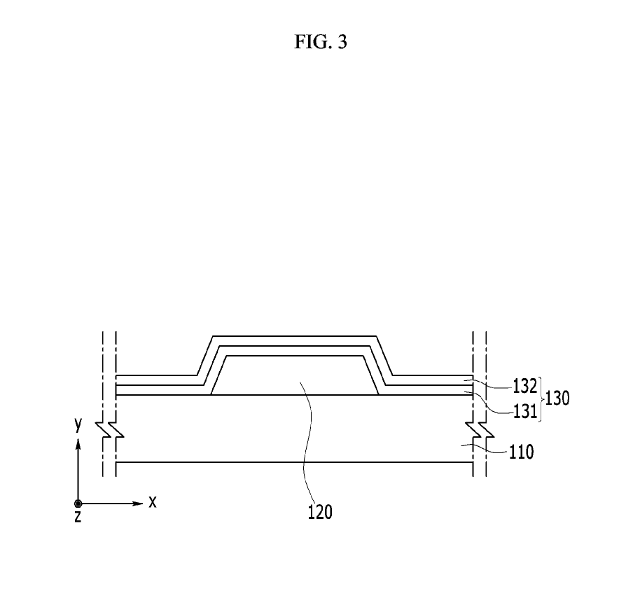

Then, as illustrated in FIG. 3, the gate metal layer 121 is etched to form a gate electrode 120.

Thereafter, a gate insulating layer 130 is formed on the gate electrode 120 and the substrate 110.

The gate insulating layer 130 includes a first insulating layer 131 positioned on the gate electrode 120 and the substrate 110, and a second insulating layer 132 positioned on the first insulating layer 131. In this case, the first insulating layer 131 and the second insulating layer 132 may include different insulating materials. For example, the first insulating layer 131 may include silicon nitride (SiNx), and the second insulating layer 132 may include silicon oxide (SiOx).

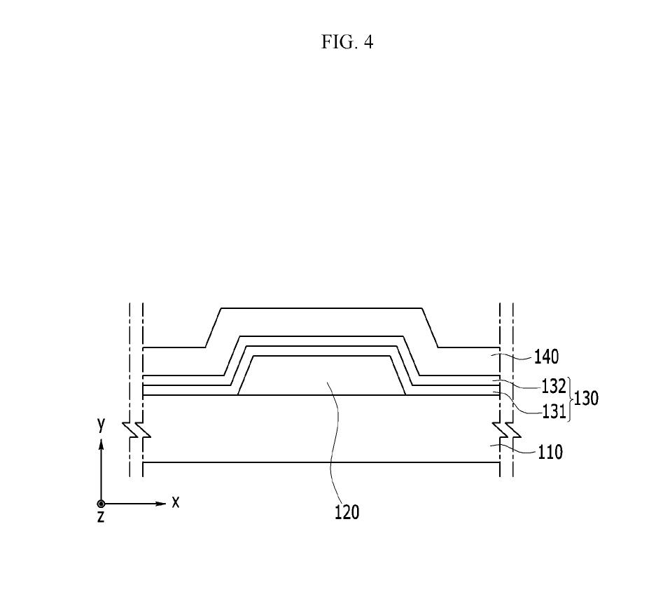

Then, as illustrated in FIG. 4, an active layer 140 is formed on the gate insulating layer 130.

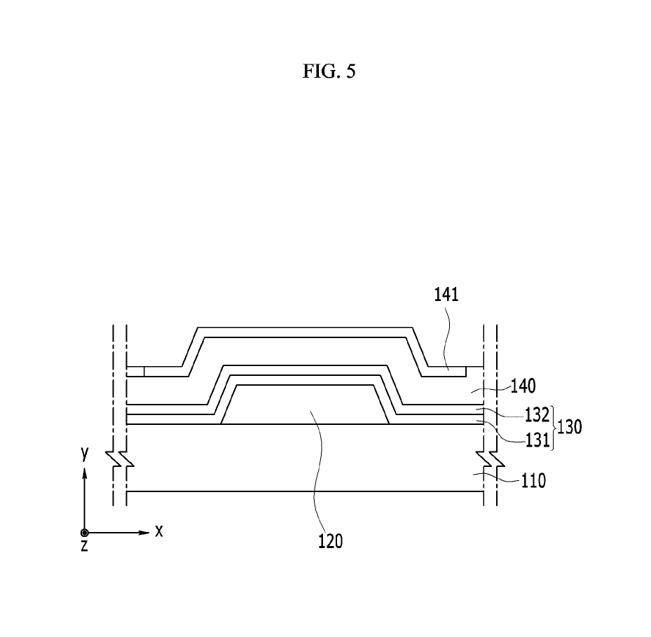

Then, as illustrated in FIG. 5, the active layer 140 is partially oxidized by anodization to form an oxide layer 141.

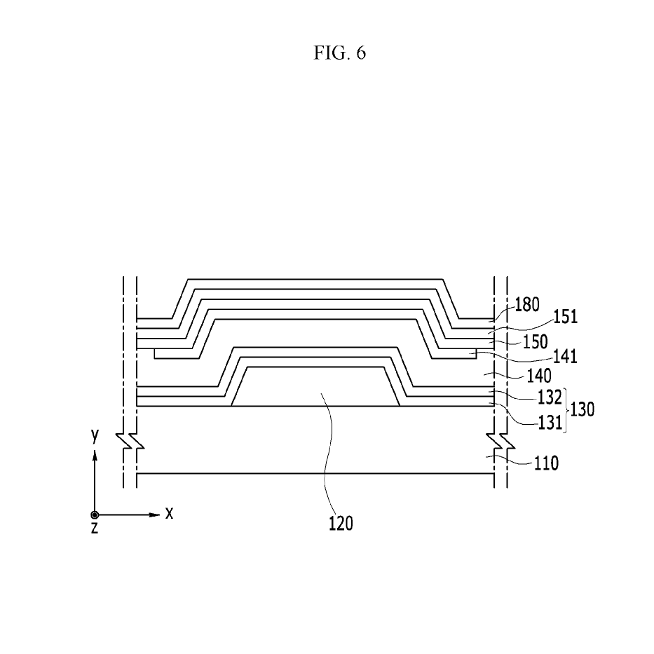

Then, as illustrated in FIG. 6, a barrier layer 150, a data metal layer 151, and a passivation layer 180 are sequentially formed on the active layer 140 and the oxide layer 141.

Then, the passivation layer 180, the data metal layer 151, and the barrier layer 150 are etched by using a photoresist pattern as a mask, and the data metal layer 151 is etched to form a source electrode 160 and a drain electrode 170. Accordingly, as illustrated in FIG. 1, the oxide layer 141 between the source electrode 160 and the drain electrode 170 may be formed as a back channel.

For example, the data metal layer may include a copper (Cu)-based metal, and the barrier layer 150 and the passivation layer 180 may be formed as a Cu barrier layer (CBL) and a Cu capping layer (CCL), respectively.

According to the method of manufacturing the thin film transistor panel as illustrated in FIGS. 2 to 6, the back channel may be strongly oxidized and insulated. The back channel may serve as a carrier suppressor by using a stronger oxygen binder than that of a back channel of the related art, such that reliability of the oxide thin film and the thin film transistor panel may be improved.

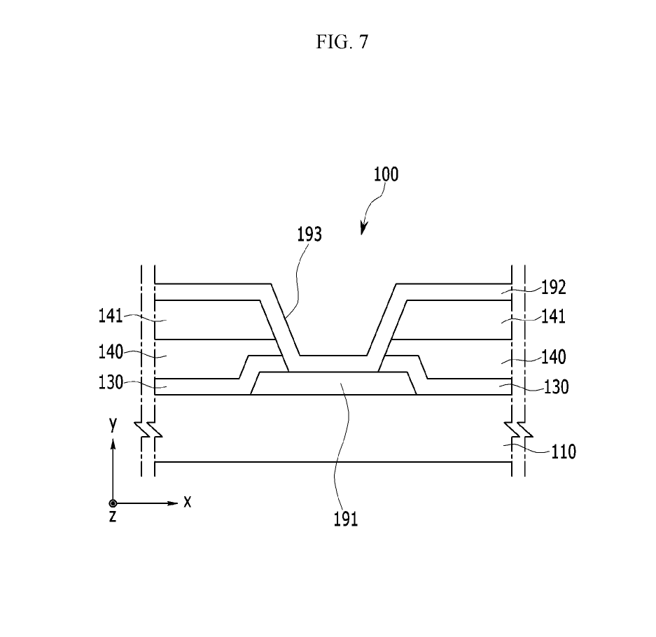

FIG. 7 is a cross-sectional view illustrating a gate pad portion of FIG. 1.

A thin film transistor panel 100 of FIG. 7 includes a substrate 110, a gate pad metal 191, a gate insulating layer 130, an active layer 140, an oxide layer 141, and a gate pad electrode 192.

The gate pad metal 191 is positioned on the substrate 110, and the gate pad electrode 192 is positioned on the oxide layer 141. In this case, the gate pad metal 191 is electrically connected to the gate pad electrode 192 through a connection hole 193.

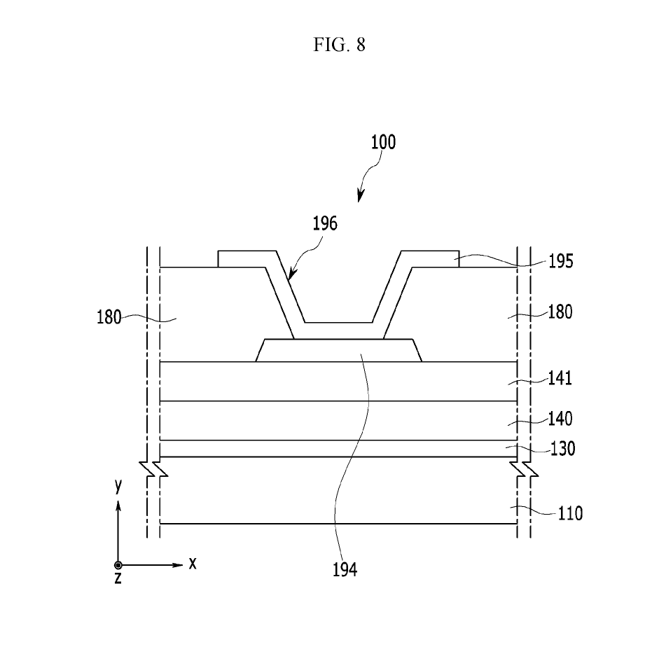

FIG. 8 is a cross-sectional view illustrating a data pad portion of FIG. 1.

A thin film transistor panel 100 of FIG. 8 includes a substrate 110, a gate insulating layer 130, an active layer 140, an oxide layer 141, a data pad metal 194, a passivation layer 180, and a data pad electrode 195.

The data pad metal 194 is positioned on the oxide layer 141, and the data pad electrode 195 is positioned on the passivation layer 180. In this case, the data pad metal 194 is electrically connected to the data pad electrode 195 through a connection hole 196.

Hereinafter, repeated descriptions of the substrate, the gate electrode, the gate insulating layer, the barrier layer, the source electrode, the drain electrode, and the passivation layer, which are the same as those of the thin film transistor panel of FIG. 1, will be omitted, and a different active layer will be described.

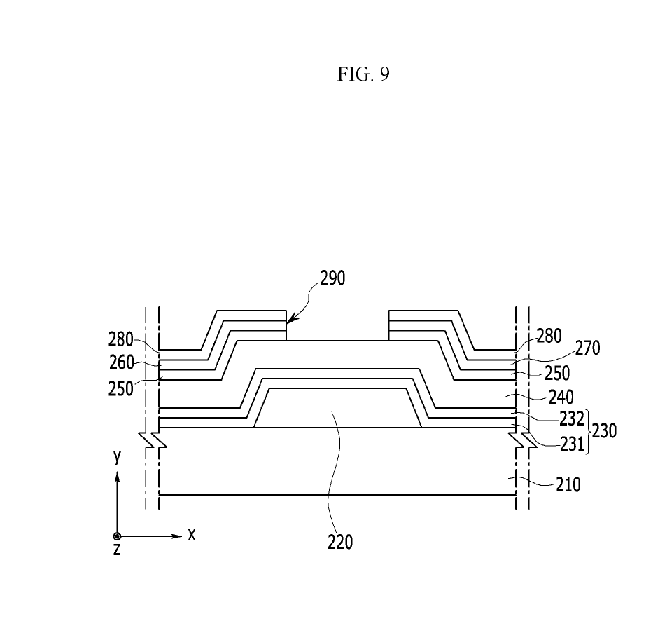

FIG. 9 is a cross-sectional view illustrating a thin film transistor panel according to an exemplary embodiment of the present invention.

A thin film transistor panel 200 of FIG. 9 includes a substrate 210, a gate electrode 220, a gate insulating layer 230, an active layer 240, a barrier layer 250, a source electrode 260, a drain electrode 270, a passivation layer 280, and an opening 290.

The active layer 240 is positioned on the gate insulating layer 230, and includes an oxide layer. In this case, the oxide layer may be formed by oxidizing the active layer 240 by anodization. Further, the oxide layer may overlap the gate electrode 220 and be substantially the same as the active layer 240.

The active layer 240 includes an oxide semiconductor active layer which is formed under an environment in which oxygen ions are not present and has high carrier mobility or a metal alloy active layer having an oxide semiconductor composition using a metal alloy target.

As a result, the carrier mobility of the active layer may be controlled to improve reliability of the thin film transistor panel. Further, a particle issue may be alleviated, and a thin film transistor panel may be manufactured by using not only a ceramic target but also a metal alloy target as a sputter target.

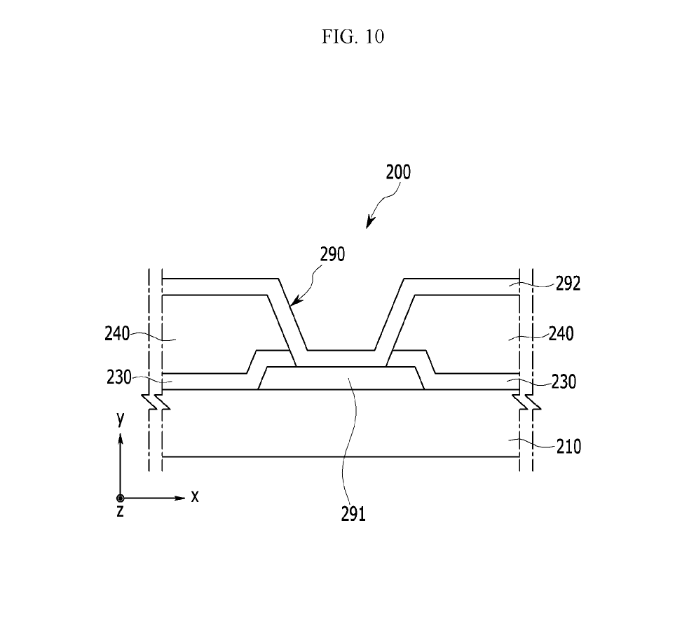

FIG. 10 is a cross-sectional view illustrating a gate pad portion of FIG. 9.

A thin film transistor panel 200 of FIG. 10 includes a substrate 210, a gate pad metal 291, a gate insulating layer 230, an active layer 240, and a gate pad electrode 292.

The gate pad metal 291 is positioned on the substrate 210, and the gate pad electrode 292 is positioned on the active layer 240. In this case, the gate pad metal 291 is electrically connected to the gate pad electrode 292 through a connection hole 293.

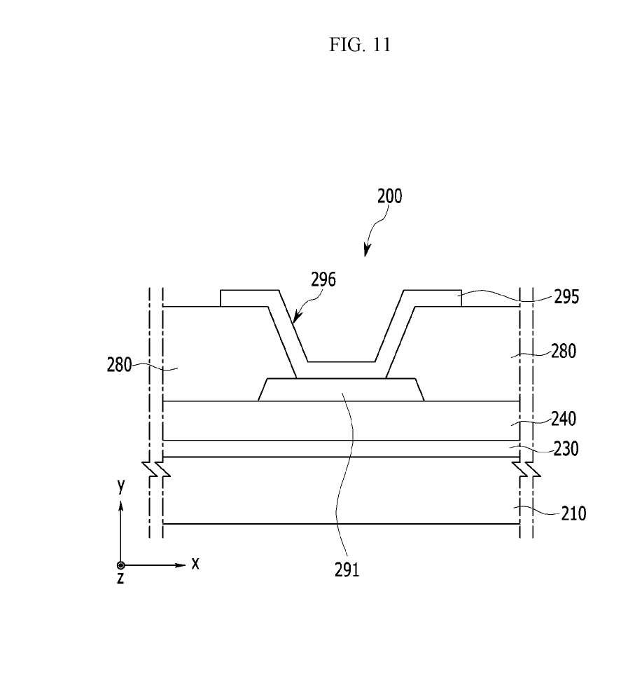

FIG. 11 is a cross-sectional view illustrating a data pad portion of FIG. 9.

A thin film transistor panel 200 of FIG. 11 includes a substrate 210, a gate insulating layer 230, an active layer 240, a data pad metal 294, a passivation layer 280, and a data pad electrode 295.

The data pad metal 294 is positioned on the active layer 240, and the data pad electrode 295 is positioned on the passivation layer 280. In this case, the data pad metal 294 is electrically connected to the data pad electrode 295 through a connection hole 296.

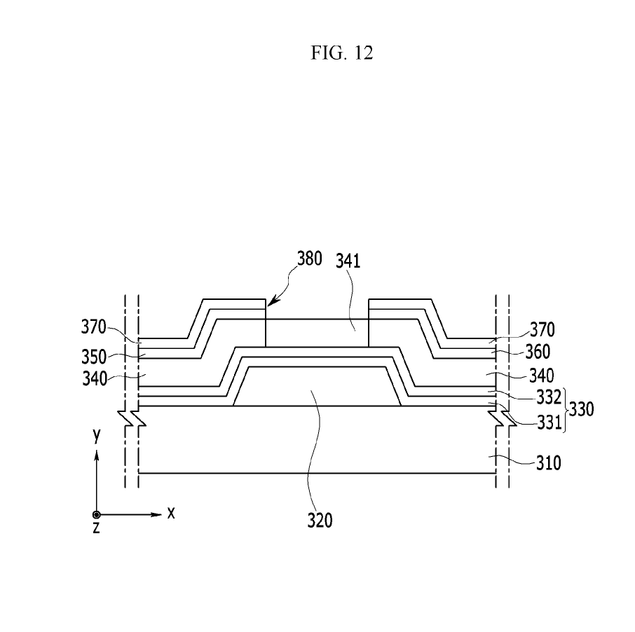

FIG. 12 is a cross-sectional view illustrating a thin film transistor panel according to an exemplary embodiment of the present invention.

A thin film transistor panel 300 of FIG. 12 includes a substrate 310, a gate electrode 320, a gate insulating layer 330, an active layer 340, an oxide layer 341, a source electrode 350, a drain electrode 360, a passivation layer 370, and an opening 380.

The active layer 340 of FIG. 12 is a conductive active layer which is formed under an environment in which oxygen ions are not present, and may be used as a source-drain contact layer, that is, a barrier layer.

The active layer 340 is positioned on the gate insulating layer 330 and includes an oxide layer 341.

The oxide layer 341 may be formed by partially oxidizing the active layer 340 by anodization, and include a back channel.

A vertical cross section of a first end of the oxide layer 341 may be positioned on substantially the same plane as a vertical cross section of the source electrode 350, and a vertical cross section of a second end of the oxide layer 341 may be positioned on substantially the same plane as a vertical cross section of the drain electrode 360.

For example, after the passivation layer 370 and the data metal layer (not illustrated in FIG. 12) are etched by using a photoresist pattern as a mask, the oxide layer 341 may be formed by oxidizing the active layer 340 before performing a photoresist strip.

Accordingly, a degree of freedom of a continuous process of forming the active layer, the source electrode, and the drain electrode is improved, the active layer has high conductivity at the remaining portion except for the back channel, and the barrier layer may be omitted.

The gate pad portion of FIG. 12 is substantially the same as that of FIG. 7.

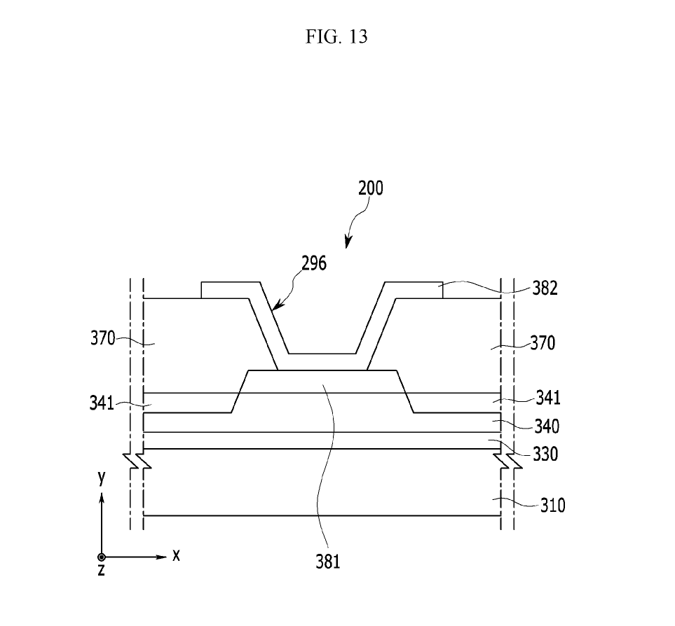

FIG. 13 is a cross-sectional view illustrating a data pad portion of FIG. 12.

A thin film transistor panel 300 of FIG. 13 includes a substrate 310, a gate insulating layer 330, an active layer 340, oxide layers 341, a data pad metal 381, a passivation layer 370, and a data pad electrode 382.

The data pad metal 381 is positioned on the active layer 340 between the oxide layers 341.

The data pad electrode 382 is positioned on the passivation layer 370.

The data pad metal 381 is electrically connected to the data pad electrode 382 through a connection hole 383.

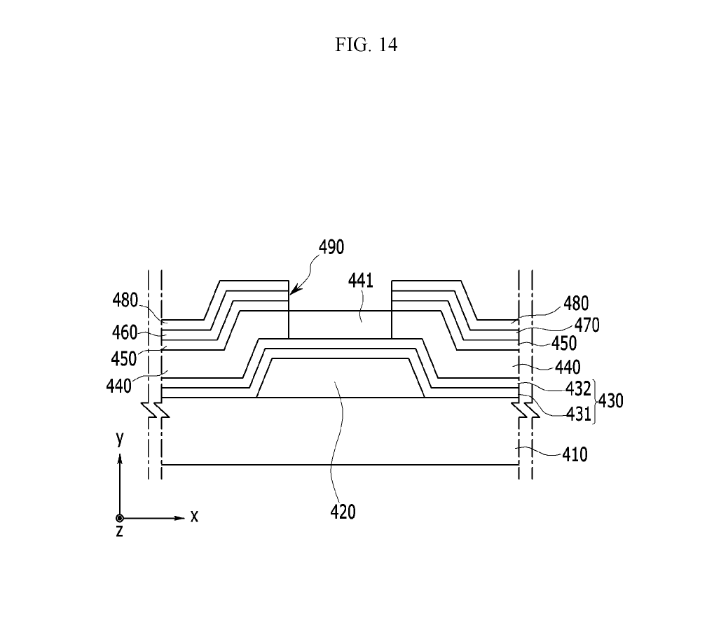

FIG. 14 is a cross-sectional view illustrating a thin film transistor panel according to an exemplary embodiment of the present invention.

A thin film transistor panel 400 of FIG. 14 includes a substrate 410, a gate electrode 420, a gate insulating layer 430, an active layer 440, an oxide layer 441, a barrier layer 450, a source electrode 460, a drain electrode 470, a passivation layer 480, and an opening 490.

The active layer 440 is positioned on the gate insulating layer 430 and includes an oxide layer 441.

The active layer 440 is formed under a proper oxygen ion environment and has a high mobility characteristic.

The oxide layer 441 may be formed by partially oxidizing the active layer 440 by anodization and include a back channel.

A vertical cross section of a first end of the oxide layer 441 may be positioned on substantially the same plane as a vertical cross section of the source electrode 460, and a vertical cross section of a second end of the oxide layer 441 may be positioned on substantially the same plane as a vertical cross section of the drain electrode 470.

For example, after the passivation layer 480 and the data metal layer (not illustrated in FIG. 14) are etched by using a photoresist pattern as a mask, the oxide layer 441 may be formed by oxidizing the active layer 440 before performing a photoresist strip.

Accordingly, the back channel may be strongly oxidized and insulated, such that reliability of the oxide thin film and the thin film transistor panel may be improved, and a mobility characteristic may also be improved.

The gate pad portion of FIG. 14 is substantially the same as that of FIG. 7, and the data pad portion is substantially the same as that of FIG. 13.

According to the exemplary embodiments of the present invention, the active layer is oxidized by anodization, such that the N20 plasma treatment process in the related art, which is performed to prevent damage to the back channel before forming the passivation layer, may be omitted. Therefore, it is possible to prevent the source-drain electrode from be oxidized and the passivation layer from cracking during the N20 plasma treatment process.

According to the exemplary embodiments of the present invention, various active layers are formed depending on an oxygen ion environment, and the active layer is oxidized by anodization, such that the carrier mobility characteristic of the oxide semiconductor thin film transistor panel may be controlled.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims

### DESCRIPTION OF SYMBOLS

110: Substrate
120: Gate electrode
130: Gate insulating layer
140: Active layer
141: Oxide layer
150: Barrier layer
160: Source electrode
170: Drain electrode
180: Passivation layer
190: Opening

1. A thin film transistor panel comprising:
a substrate;
a gate electrode positioned on the substrate;
a gate insulating layer positioned on the gate electrode;
an oxide semiconductor positioned on the gate insulating layer and including an oxide layer; and
a source electrode and a drain electrode positioned on the oxide semiconductor and a channel of the oxide semiconductor, and contacting a protruding top surface of the oxide layer,
wherein the oxide layer overlaps the gate electrode and is positioned on a portion of the oxide semiconductor which is not the oxide layer.

2. The thin film transistor panel of claim 1, wherein:
a top surface of the oxide layer and the top surface of the oxide semiconductor are positioned on substantially the same plane.

3. The thin film transistor panel of claim 1, wherein:
the oxide layer is partially exposed from the source electrode and the drain electrode.

4. The thin film transistor panel of claim 1, wherein:
a first end of the oxide layer overlaps the source electrode, and a second end of the oxide layer overlaps the drain electrode.

5. The thin film transistor panel of claim 1, wherein:
the oxide layer is substantially the same as the oxide semiconductor.

6. The thin film transistor panel of claim 5, wherein:
the oxide semiconductor includes a metal alloy semiconductor having an oxide semiconductor composition.

7. The thin film transistor panel of claim 1, further comprising:
a barrier layer positioned on the oxide semiconductor; and
a passivation layer positioned on the source electrode and the drain electrode.

8. The thin film transistor panel of claim 7, comprising:
a data pad metal positioned on the oxide layer; and
a data pad electrode positioned on the passivation layer,
wherein the data pad metal is connected to the data pad electrode through a connection hole.

9. The thin film transistor panel of claim 1, comprising:
a gate pad metal positioned on the substrate; and
a gate pad electrode positioned on the oxide layer,
wherein the gate pad metal is connected to the gate pad electrode through a connection hole.

10. The thin film transistor panel of claim 1, wherein:
a vertical cross section of the first end of the oxide layer is positioned on substantially the same plane as a vertical cross section of the source electrode, and a vertical cross section of the second end of the oxide layer is positioned on substantially the same plane as a vertical cross section of the drain electrode.

11. The thin film transistor panel of claim 10, further comprising:
a passivation layer positioned on the source electrode and the drain electrode.

12. The thin film transistor panel of claim 11, comprising:
a data pad metal positioned on the active layer; and
a data pad electrode positioned on the passivation layer,
wherein the data pad metal is connected to the data pad electrode through a connection hole.

13. The thin film transistor panel of claim 10, further comprising:
a barrier layer positioned on the oxide semiconductor; and
a passivation layer positioned on the source electrode and the drain electrode.

14. The thin film transistor panel of claim 13, comprising:
a data pad metal positioned on the active layer between the oxide layers; and
a data pad electrode positioned on the passivation layer,
wherein the data pad metal is connected to the data pad electrode through a connection hole.

15. A method of manufacturing a thin film transistor panel, the method comprising:
forming a gate electrode on a substrate;
forming a gate insulating layer on the gate electrode;
forming an oxide semiconductor on the gate insulating layer;
forming an oxide layer by partially or wholly oxidizing the oxide semiconductor by anodization; and
forming a source electrode and a drain electrode, which face each other based on a channel of the oxide semiconductor, on the oxide layer.

16. The method of claim 15, further comprising:
forming a barrier layer on the oxide layer; and
forming a passivation layer on the source electrode and the drain electrode.

17. The method of claim 15, wherein:
the forming of the oxide semiconductor on the gate insulating layer includes forming the oxide semiconductor under an environment in which oxygen ions are not present.

18. A method of manufacturing a thin film transistor panel, the method comprising:
forming a gate electrode on a substrate;
forming a gate insulating layer on the gate electrode;
forming an oxide semiconductor on the gate insulating layer;
forming a source electrode and a drain electrode, which face each other based on a channel of the oxide semiconductor, on the oxide semiconductor;
forming a passivation layer on the source electrode and the drain electrode; and
forming an oxide layer by oxidizing a channel of the oxide semiconductor by anodization.

19. The method of claim 18, wherein:
the forming of the oxide semiconductor on the gate insulating layer includes forming the oxide semiconductor under an environment in which oxygen ions are not present.

20. The method of claim 18, wherein:
the forming of the oxide semiconductor on the gate insulating layer includes forming the oxide semiconductor under an environment in which oxygen ions are present.

21. The method of claim 18, further comprising:
forming a barrier layer on the oxide semiconductor.
